(19) United States
(12) Patent Application Publication
(10) Pub. No.: US 2012/0123726 A1
(43) Pub. Date: May 17, 2012

(54) TEST APPARATUS, TEST METHOD, AND STORAGE MEDIUM

(75) Inventor: Mitsuru SAKAI, Saitama (JP)

(73) Assignee: ADVANTEST CORPORATION, Tokyo (JP)

(21) Appl. No.: 13/084,561

(22) Filed: Apr. 12, 2011

Related U.S. Application Data
(63) Continuation of application No. PCT/JP2008/003395, filed on Nov. 19, 2008.

(51) Int. Cl. G06F 19/00; G01R 31/00

(52) U.S. Cl. 702/117

(57) ABSTRACT

The time required for timing training is reduced by a test apparatus having an expected value comparing section judging whether a value resulting from sampling input/output data using a strobe signal matches a pre-set expected value a pre-set number of times, and a test section adjusting a phase of a test signal to be supplied to the device under test based on the first relative phase changing from a fail state to a pass state and the second relative phase changing from the pass state to the fail state, and testing the device under test using the test signal whose phase has been adjusted, where the fail state being in which at least one of the pre-set number of judgment results indicates mismatch, and the pass state being in which all the pre-set number of judgment results indicate match.

### BACKGROUND

1. Technical Field

The present invention relates to a test apparatus, a test method, and a storage medium.

2. Related Art

When testing a semiconductor device, a semiconductor test apparatus exchanges, with a device under test, data synchronized to a clock. To assuredly exchange the data, the data sampling should be desirably conducted at the central position of the data. When the frequency of the data is high, however, the effect of the skew due to wiring length and jitter become large in relation to the UI (unit interval) which is a unit length of data. As a result, the eye opening of the data received by the semiconductor test apparatus and the device under test becomes small. Consequently, the semiconductor test apparatus is required to perform timing training for adjusting the timing between the clock and the data, for the purpose of sampling the data at the chronological central position of the eye opening.

The timing training is roughly classified into read training performed when reading data from a device under test, and write training performed when writing data to a device under test. In read training, a semiconductor test apparatus adjusts the phase of a strobe signal for latching, so as to latch the data received from the device under test in the vicinity of the central position of the eye opening. In write training, the semiconductor test apparatus adjusts the phase of the data outputted to the device under test, so as to latch the data received by the device under test in the vicinity of the central position of the eye opening. The related technical document that we are currently aware of is Japanese Patent Application Publication No. 2004-125574.

For detecting the central position of the eye opening, the semiconductor test apparatus sequentially changes the relative phase of the data and the strobe, and judges whether the received data matches the expected value at the respective relative phases. When judging that the received data does not match the expected value, the semiconductor test apparatus judges that the relative phase is in the fail state in which the data cannot be normally transmitted or received. When judging that the received data matches the expected value, the semiconductor test apparatus judges that the relative phase is in the pass state in which the data can be normally transmitted or received.

Therefore, the semiconductor test apparatus sets the initial phase of the relative phase in the pass state, and detects the left-edge of the eye opening by shifting the relative phase to the left, and the right-edge of the eye opening by shifting the relative phase to the right. However, since the data outputted from the device under test and the phase of the strobe in the device under test are indeterminate, it is difficult to set the initial phase of the relative phase in the pass state. As a result, it takes long to detect the edge of the eye opening, which is problematic.

### SUMMARY

Therefore, it is an object of an aspect of the innovations herein to provide a test apparatus, a test method, and a recording medium, which are capable of overcoming the above drawbacks accompanying the related art. The above and other objects can be achieved by combinations described in the claims. A first aspect of the innovations may include a test apparatus for testing a device under test, including: a phase control section that sequentially changes a relative phase of input/output data of the device under test and a pre-set strobe signal, into one pre-set direction; an expected value comparing section that judges whether a value resulting from sampling the input/output data using the strobe signal matches a pre-set expected value a pre-set number of times at each relative phases; a phase detecting section that detects a first relative phase changing from a fail state to a pass state and a second relative phase changing from the pass state to the fail state, the fail state being in which at least one of the pre-set number of judgment results indicates mismatch, and the pass state being in which all the pre-set number of judgment results indicate match; a phase adjusting section that adjusts a phase of a test signal to be supplied to the device under test based on the first relative phase and the second relative phase detected by the phase detecting section; and a test section that tests the device under test using the test signal whose phase has been adjusted by the phase adjusting section.

A second aspect of the innovations may include a test method for testing a device under test, including: sequentially changing a relative phase of input/output data of the device under test and a pre-set strobe signal, into one pre-set direction; judging whether a value resulting from sampling the input/output data using the strobe signal matches a pre-set expected value a pre-set number of times at each relative phases; detecting a first relative phase changing from a fail state to a pass state and a second relative phase changing from the pass state to the fail state, the fail state being in which at least one of the pre-set number of judgment results indicates mismatch, and the pass state being in which all the pre-set number of judgment results indicate match; adjusting a phase of a test signal to be supplied to the device under test based on the first relative phase and the second relative phase; and testing the device under test using the test signal whose phase has been adjusted.

A third aspect of the innovations may include a recording medium storing a program to operate a test apparatus that tests a device under test, the program causing the test apparatus to function as: a phase control section that sequentially changes a relative phase of input/output data of the device under test and a pre-set strobe signal, into one pre-set direction; an expected value comparing section that judges whether a value resulting from sampling the input/output data using the strobe signal matches a pre-set expected value a pre-set number of times at each relative phases; a phase detecting section that detects a first relative phase changing from a fail state to a pass state and a second relative phase changing from the pass state to the fail state, the fail state being in which at least one of the pre-set number of judgment results indicates mismatch, and the pass state being in which all the pre-set number of judgment results indicate match; a phase adjusting section that adjusts a phase of a test signal to be supplied to the device under test based on the first relative phase and the second relative phase detected by the phase detecting section; and a test section that tests the device under test using the test signal whose phase has been adjusted by the phase adjusting section.

The summary clause does not necessarily describe all necessary features of the embodiments of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 shows a configuration of a semiconductor test apparatus 100 according to the present embodiment.

FIG. 2 shows a read training procedure of the semiconductor test apparatus 100 according to the present embodiment.

FIG. 3 shows a write training procedure of the semiconductor test apparatus 100 according to the present embodiment.

FIG. 4 is a flowchart showing timing training and test of a device under test performed in the semiconductor test apparatus 100 according to the present embodiment.

FIG. 5 shows a read training procedure of the semiconductor test apparatus 100 according to the second embodiment.

FIG. 6 shows a read training procedure of the semiconductor test apparatus 100 according to the third embodiment.

FIG. 7 shows a configuration of the semiconductor test apparatus 100 according to the fourth embodiment.

FIG. 8 shows a configuration of the semiconductor test apparatus 100 according to the fifth embodiment.

### DESCRIPTION OF EXEMPLARY EMBODIMENTS

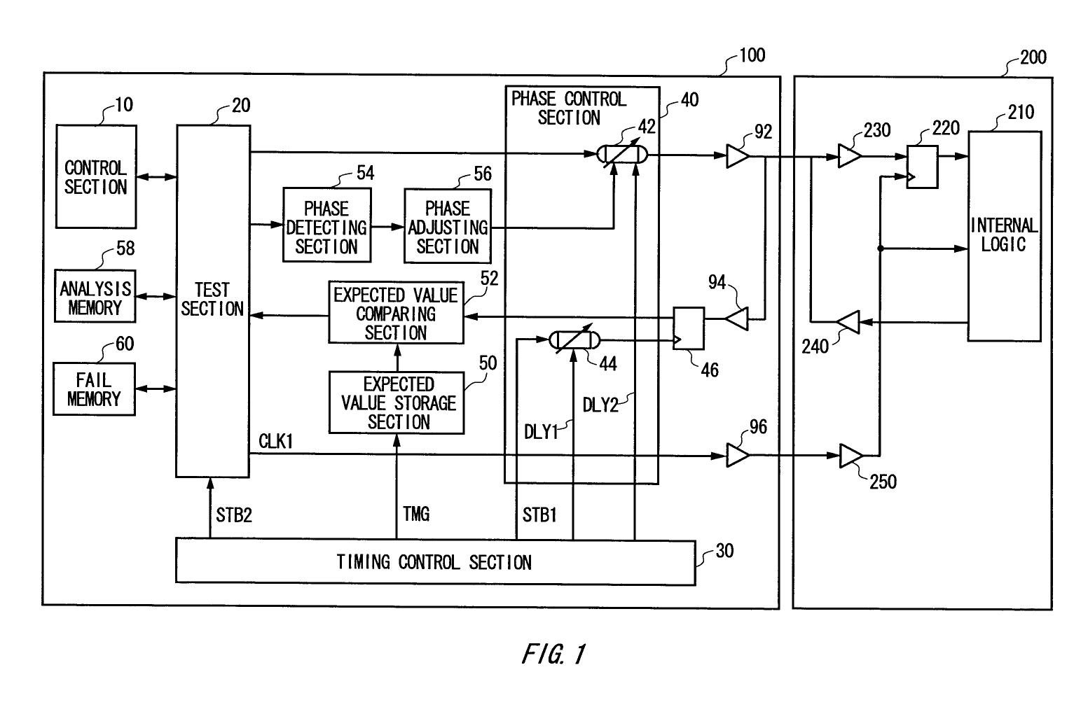

FIG. 1 shows a configuration of a semiconductor test apparatus 100 according to the present embodiment. The semiconductor test apparatus 100 includes a control section 10, a test section 20, a timing control section 30, a phase control section 40, a timing comparator 46, an expected value storage section 50, an expected value comparing section 52, a phase detecting section 54, a phase adjusting section 56, an analysis memory 58, a fail memory 60, a driver 92, a level comparator 94, and a driver 96. The device under test 200 includes an internal logic 210, a timing comparator 220, a level comparator 230, a driver 240, and a level comparator 250.

In the present example, the control section 10 controls the test of the device under test 200. The control section 10 may be a CPU operating according to the program stored in the nonvolatile memory. The test section 20 generates data and a clock used in the timing training and the test of the device under test 200. In addition, the test section 20 judges the test result based on the data received from the device under test 200.

The timing control section 30 generates a timing signal, a strobe signal, and a setting signal used in the timing training and the test of the device under test 200. The timing control section 30 ma supply the strobe signal STB1 and the setting signal DLY1 to the delay circuit 44, the strobe signal STB2 to the test section 20, the timing signal TMG to the expected value storage section 50, and the setting signal DLY2 to the delay circuit 42. The setting signal DLY1 and the setting signal DLY2 are respectively signals representing values setting the delay amounts for the delay circuit 44 and the delay circuit 42.

The phase control section 40 includes the delay circuit 42 and the delay circuit 44, and controls the phase of the data and the strobe signal inputted to the phase control section 40, according to the setting signal outputted from the timing control section 30. When performing timing training, the phase control section 40 sequentially changes the relative phase of the input/output data of the device under test 200 and the strobe signal outputted from the timing control section 30, to one predetermined direction. For example, when performing read training, the phase control section 40 may sequentially change the relative phase of the data outputted from the device under test 200 and the strobe signal used for latching the data. Note that the phase control section 40 may change only the phase of the input/output data, or may change both of the phase of the input/output data and the phase of the strobe signal.

To be specific, the timing control section 30 generates the strobe signal STB1 for latching the data outputted from the device under test 200. The delay circuit 44 may delay the strobe signal STB1 based on the timing signal DLY1 outputted from the timing control section 30. By sequentially delaying the timing signal DLY1, the relative phase of the strobe signal outputted from the delay circuit 44 sequentially delayed.

The timing comparator 46 latches the data received from the device under test 200, by means of the strobe signal whose relative phase has been changed by the delay circuit 44. The timing comparator 46 transmits the latched data to the expected value comparing section 52. The data outputted from the timing comparator 46 may be a logical signal of “1” or “0.”

When performing write training, the semiconductor test apparatus 100 may sequentially change the relative phase of the clock and the data outputted to the device under test 200. The test section 20 generates the clock and the data outputted to the device under test 200. The test section 20 may generate the clock CLK1 outputted to the device under test 200, based on the strobe signal STB2 generated by the timing control section 30.

The delay circuit 42 delays the data received from the test section 20, to change the relative phase in relation to the clock CLK1. The delay circuit 42 transmits the delayed data to the device under test 200. The delay circuit 42 may determine the delay amount based on the timing signal DLY2 outputted from the timing control section 30.

The device under test 200 may latch the data delayed by the delay circuit 42, based on the clock CLK1 generated by the test section 20. The semiconductor test apparatus 100 may judge whether the device under test 200 has normally received the data at each relative phase by receiving the response data generated according to the data latched by the device under test 200.

The expected value storage section 50 stores the expected value for the data received from the device under test 200. The expected value storage section 50 may store the expected value used in the timing training and the expected value used in the test of the device under test 200. The expected value storage section 50 may include a nonvolatile memory, and may output the stored expected value to the expected value comparing section 52, based on the timing signal TMG outputted from the timing control section 30.

The expected value comparing section 52 judges whether the value resulting from sampling the data inputted or outputted with respect to the device under test 200 by means of the strobe signal outputted from the timing control section 30 matches a predetermined expected value, a plurality of times at each relative phase. For example, when the output value from the timing comparator 46 as a result of the sampling is “1” and the expected value outputted from the expected value storage section 50 is also “1,” the expected value comparing section 52 may judge that the data matches the expected value. On the contrary, when the output value from the timing comparator 46 as a result of the sampling is “1” and the expected value outputted from the expected value storage section 50 is “0,” the expected value comparing section 52 may judge that the data does not match the expected value.

Furthermore, the expected value comparing section 52 may store the judgment result in each sampling to the analysis memory 58 connected to the test section 20. For example, the expected value comparing section 52 may store “0” to the analysis memory 58 for the sampling value matching the expected value, and may store “1” to the analysis memory 58 for the sampling value not matching the expected value.

The phase detecting section 54 reads the judgment result stored in the analysis memory 58. Furthermore, the phase detecting section 54 detects the first relative phase changing from the fail state indicating that at least one of a predetermined number of the judgment results indicates mismatch, to the pass state indicating that all the predetermined number of judgment results indicate match, and also the second relative phase changing from the pass state to the fail state.

For example, the phase detecting section 54 may read, from the analysis memory 58, the judgment result at each sampling for each relative phase, and may determine that it is in the fail state when the read judgment result includes a predetermined number or more of “1” (in the present example, one or more “1”). When a predetermined number or more (in the present example, all) of the values sampled a predetermined number of times at each relative phase are “0,” the phase detecting section 54 may judge that it is in the pass state. Then, the phase detecting section 54 may determine that the relative phase at which the judgment result changes from the fail state to the pass state is the first relative phase, and the relative phase at which the judgment result changes from the pass state to the fail state is the second relative phase.

The phase adjusting section 56 adjusts the phase of the test signal to be supplied to the device under test 200, based on the first relative phase and the second relative phase detected by the phase detecting section 54. For example, when testing the device under test 200, the phase detecting section 54 may change the phase of the test data outputted from the test section 20 forward and backward, so as to set the relative phase of the test data and the test clock outputted from the test section 20, to be substantially the middle phase between the first relative phase and the second relative phase. By adjusting in the above way, the device under test 200 can sample the received test data substantially at the central position of the eye opening.

The test section 20 tests the device under test 200, using the test signal whose phase has been adjusted by the phase adjusting section 56. For example, the test section 20 may transmit, to the device under test 200, the test data including the digital data of “1” and “0” based on a predetermined logical vector and the test clock synchronized to the test data. The relative phase of the test data and the test clock may be the relative phase having been obtained in the write training.

The device under test 200 generates response data in the internal logic 210 according to the received test data, and outputs the generated response data to the semiconductor test apparatus 100. In the semiconductor test apparatus 100, the response data received from the device under test 200 is latched by the timing comparator 46. The timing comparator 46 may latch the received data, by means of the strobe signal having the relative phase obtained in the read training. The expected value comparing section 52 compares the expected value and the data received from the device under test 200, and outputs the comparison result to the test section 20. The test section 20 may judge pass/fail of the device under test 200 based on the comparison result, and store the judgment result to the fail memory 60.

Note that the timing control section 30 may start generating a timing signal, a strobe signal, and a setting signal, upon being triggered by the control section 10. The test section 20 and the timing control section 30 may operate at the same clock. Consequently, the semiconductor test apparatus 100 does not have to use a bus of the control section 10 to transmit the signal for timing training. A bus is not required when analyzing the data received from the device under test 200, either. As a result, the semiconductor test apparatus 100 according to the present embodiment can perform timing training quicker than in a case where a controlling method that has to use a bus is adopted.

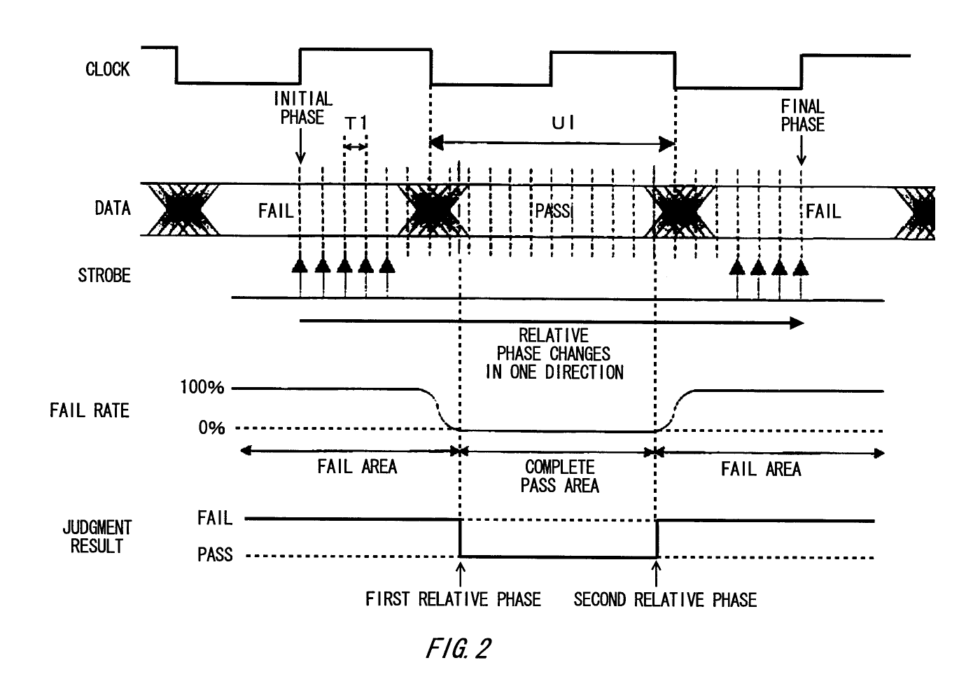

FIG. 2 shows a read training procedure of the semiconductor test apparatus 100 according to the present embodiment. In this drawing, “clock” represents a clock that the semiconductor test apparatus 100 transmits to the device under test 200. “Data” represents data outputted from the device under test 200. “Strobe” represents a strobe signal outputted from the delay circuit 44. “UI” represents the length of a unit of data outputted from the device under test 200.

The device under test 200 may output data synchronized to the trailing edge of the inputted clock. In addition, during the timing training, the semiconductor test apparatus 100 may control the device under test 200, so as to output data of a value matching the expected value only at one cycle, and to output data of a value not matching the expected value during the other cycles. Note that 1 UI may be an integral multiple of the length of 1 period of clock.

The phase of the data outputted from the device under test 200 fluctuates with respect to the phase of the clock outputted from the semiconductor test apparatus 100, due to the effect of the jitter attributed to the power source noise or the like. As a result, it occasionally happens that a value different from the data value outputted from the device under test 200 is obtained in the vicinity of the change point of the data. Accordingly, so as to obtain the data received from the device under test 200 without an error, the semiconductor test apparatus 100 should desirably samples at the central position of the eye opening, and not in the vicinity of the change point of the data.

Therefore, so as to detect the phase of the strobe signal used for sampling at the central position of the eye opening, the phase control section 40 sequentially changes the phase of the strobe signal outputted from the timing control section 30, based on the timing signal outputted from the timing control section 30. For example, the phase control section 40 may change the relative phase of the strobe signal from the initial phase position to the final phase, in one direction and the phase interval of T1.

To be specific, upon start of read training, the delay circuit 44 generates a strobe signal whose relative phase in relation to the data is at the initial phase. At this relative phase, the expected value comparing section 52 performs comparison with the expected value a predetermined number of times, and stores the judgment result to the analysis memory 58. After ending the measurement at this relative phase, the timing control section 30 switches the timing signal to be outputted to the delay circuit 44. The delay circuit 44 generates a strobe signal whose phase is different from the initial phase by T1, based on the timing signal after switching. The expected value comparing section 52 performs comparison with the expected value a predetermined number of times at this relative phase. The delay circuit 44 may repeat the change for each T1, until the phase of the strobe signal reaches the final phase.

“Fail rate” in FIG. 2 represents a ratio of data that the expected value comparing section 52 has judged not to match the expected value, to the data sampled a predetermined number of times at each relative phase. For example, when the test section 20 performs 100 times of sampling at one relative phase, the sampled data and the expected value read from the expected value storage section 50 are different 100 times, the fail rate is 100%. Likewise, when the sampled data is different from the expected value read from the expected value storage section 50, 50 times, the fail rate is 50%. When the sampled data and the expected value match all the times, the fail rate is 0%.

“Judgment result” represents a result of judging by the phase detecting section 54 as to whether it is a fail state or a pass state, based on the judgment result of the expected value comparing section 52 stored in the analysis memory 58. In the present embodiment, the relative phase in which the fail rate is not 0% is judged to be the fail state, and the relative phase in which the fail rate is 0% is judged to be the pass state. As a result, the first relative phase changing from the fail state to the pass state and the second relative phase changing from the pass state to the fail state are detected.

Here, when the relative phase at the start of the timing training is not determined, the semiconductor test apparatus 100 cannot recognize whether the relative phase is in the pass state or the in the fail state at the start of the timing training. As a result, it may take long before the semiconductor test apparatus 100 detects the first relative phase. For example, if the change in relative phase starts from the phase between the first relative phase and the second relative phase towards the final phase direction, the first relative phase changing from the fail state to the pass state cannot be detected. Accordingly, the semiconductor test apparatus 100 has to change the relative phase by switching to the initial phase direction after detecting the second relative phase.

With this in view, the phase control section 40 may set the initial phase of a strobe signal to the phase according to which the fail state is detected. For example, the phase control section 40 may set the initial phase at a position distant from the central position of the eye opening by 0.5 UI to 1.5 UI. At the relative phase of 0.5 UI to 1.5 UI, there is a chance that the reception data is different from the expected value, and so the fail rate does not become 0%. Therefore, by setting the initial phase within this range, the semiconductor test apparatus 100 can assuredly detect the first relative phase changing from the fail state to the pass state, simply by changing the relative phase into one direction. In addition, by further changing the relative phase after detection of the first relative phase, the second relative phase can be detected. As a result, the advantageous effect of reducing the time required for the timing training can be achieved.

The semiconductor test apparatus 100 may detect the relative phase changing from the fail state to the pass state and the relative phase changing from the pass state to the fail state, by sequentially changing the relative phase of a strobe signal and then analyzing the data received from the device under test 200. The phase detecting section 54 may detect the first relative phase and the second relative phase, based on the data stored in the analysis memory 58.

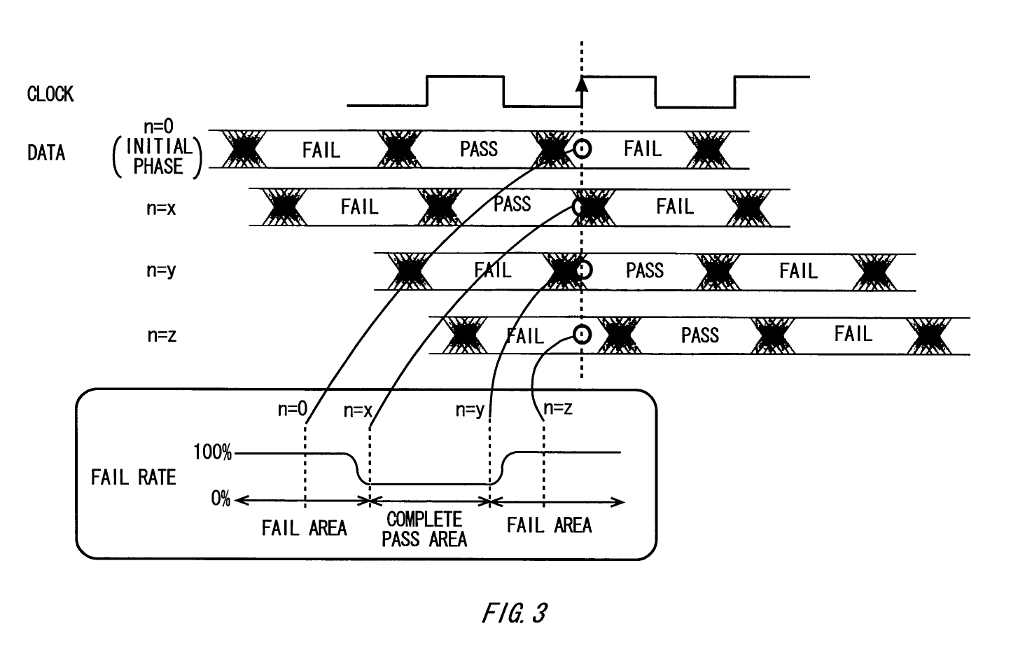

FIG. 3 shows a write training procedure of the semiconductor test apparatus 100 according to the present embodiment. In this drawing, “clock” represents a strobe signal that the semiconductor test apparatus 100 transmits to the device under test 200. “Data” represents data that the semiconductor test apparatus 100 transmits to the device under test 200. The device under test 200 may obtain the reception data by latching the data at the leading edge of the inputted clock. Furthermore, the device under test 200 may transmit, to the semiconductor test apparatus 100, data in accordance with the obtained data. The semiconductor test apparatus 100 may judge whether the device under test 200 has normally obtained the data, by comparing the expected value to the data received from the device under test 200.

Here, it is desirable that the device under test 200 samples the data at the central position of the eye opening of the data received from the semiconductor test apparatus 100. With this in view, the semiconductor test apparatus 100 controls the phase of the data transmitted to the device under test 200, so as to cause the sampling position of the device under test 200 to substantially match the eye opening central position of the data.

That is, the phase control section 40 sequentially changes the relative phase of the input data given to the device under test 200 and the clock corresponding to the strobe signal used for sampling the input data within the device under test 200, into a predetermined direction. For example, the phase control section 40 may sequentially change the relative phase of the clock and the data outputted to the device under test 200, by changing the delay amount to be applied to the data outputted to the device under test 200. The phase control section 40 may also change the relative phase, either by changing the delay amount to be applied to the clock or by changing the delay amount to be applied to each of the data and the clock.

Upon reception of the data from the semiconductor test apparatus 100, the timing comparator 220 latches the data by means of the strobe signal received from the semiconductor test apparatus 100, and outputs the data to the internal logic 210. The internal logic 210 transmits the latch signal received from the timing comparator 220, via the driver 240 to the semiconductor test apparatus 100, The semiconductor test apparatus 100 may provide the device under test 200 with a control signal enabling to output a signal of a UI larger than the UI of the signal transmitted from the semiconductor test apparatus 100.

The expected value comparing section 52 receives, from the device under test 200, the value of the input data obtained by the device under test 200 according to the strobe signal. For example, the expected value comparing section 52 may receive the data outputted from the device under test 200, via the phase control section 40. The phase control section 40 latches the data received from the device under test 200 by means of the strobe signal outputted from the delay circuit 44, and transmits the latched data to the expected value comparing section 52. The expected value comparing section 52 may judge whether the data received from the phase control section 40 matches the expected value read from the expected value storage section 50.

A plurality of pieces of “data” shown in FIG. 3 represent a plurality of pieces of data having respectively different relative phases generated by the delay circuit 42 by delaying the data generated by the test section 20. “n” represents the relative phase of the data in relation to the clock, and when n=0, it means that the relative phase is the initial phase. The semiconductor test apparatus 100 estimates the central position of the eye opening of the data inputted to the timing comparator 220, and sets the initial phase so as to latch the data at a position distant from the estimated position by 0.5 UI or more. As a result, at the relative phase when n=0, the judgment result of the phase detecting section 54 results in the fail state.

At the relative phase when n=x, the timing comparator 220 latches the data at the first boundary position of the eye opening of the data. As a result, the judgment result of the phase detecting section 54 at n=x changes from the fail state to the pass state. At the relative phase when n=y, the timing comparator 220 latches the data at the second boundary position of the eye opening of the data. As a result, the judgment result of the phase detecting section 54 at n=y changes from the pass state to the fail state. At the relative phase when n=z, the timing comparator 220 latches the data at a position distant by 0.5 UI or more from the central position of the eye opening of the data. As a result, the judgment result of the phase detecting section 54 at n=z is the fail state.

According to the above-explained procedure, the phase detecting section 54 detects that n=x is the first relative phase changing from the fail state to the pass state, and n=y is the second relative phase changing from the pass state to the fail state. Based on the first relative phase and the second relative phase having been detected, the semiconductor test apparatus 100 may control the phase of data, so as to cause the leading edge of the clock outputted to the device under test 200, to substantially match the central position of the eye opening of the data outputted to the device under test 200.

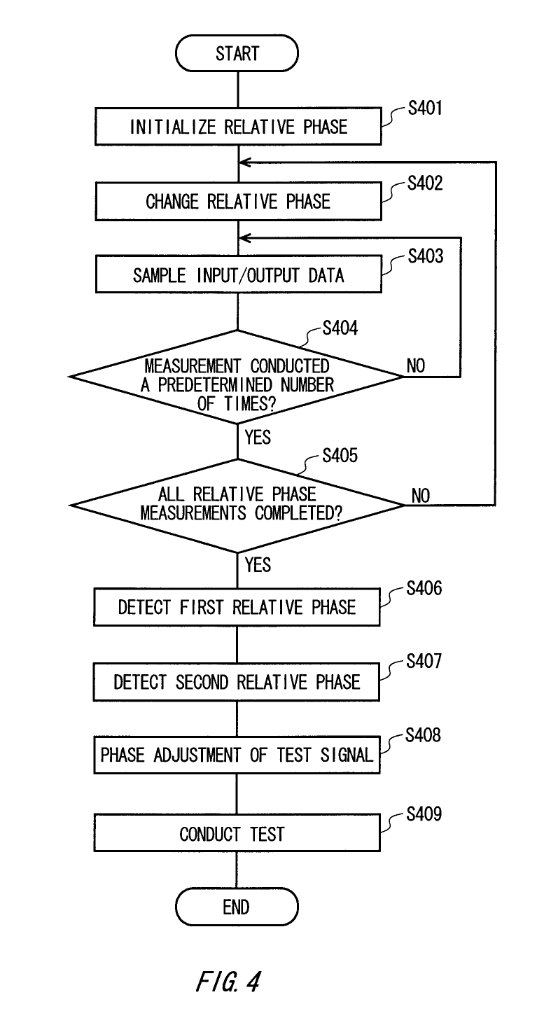

FIG. 4 is a flowchart showing timing training and test of a device under test performed in the semiconductor test apparatus 100 according to the present embodiment. When performing a test of a data output function of the device under test 200, the semiconductor test apparatus 100 sets the relative phase of the received data and the strobe signal used for latching the data, to the initial phase, in the timing control section 30 (S401). Subsequently, the timing control section 30 delays the strobe signal by a predetermined amount, and changes the relative phase (S402).

At this relative phase, the timing comparator 46 samples the data received from the device under test 200, and outputs the sampled data to the expected value comparator 52 (S403). The expected value comparing section 52 judges whether the received data matches the expected value read from the expected value storage section 50, and stores the judgment result to the analysis memory 58. When a predetermined number of data sampling has been completed at the relative phase set in S402 (S404), the timing control section 30 changes the relative phase again (S402), and conducts S403 and S404.

After data sampling at all the relative phases has been completed (S405), the phase detecting section 54 detects the first relative phase based on the judgment data stored in the analysis memory 58 (S406). Subsequently, the phase detecting section 54 detects the second relative phase based on the judgment data stored in the analysis memory 58 (S407).

The phase adjusting section 56 adjusts the phase of the test signal to be supplied to the device under test 200, based on the first relative phase and the second relative phase (S408). For example, the phase adjusting section 56 may change the phase of the data to be transmitted, forward and backward, so that the leading position of the clock transmitted to the device under test 200 from the semiconductor test apparatus 100 substantially matches the central position of the eye opening of the data transmitted to the device under test 200 from the semiconductor test apparatus 100.

The semiconductor test apparatus 100 outputs, to the device under test 200, the clock outputted from the test section 20 as well as the data whose phase has been adjusted by the phase adjusting section 56, as a test signal. The device under test 200 transmits, to the semiconductor test apparatus 100, the data according to the received test signal, and performs judgment in the test section 20 (S409).

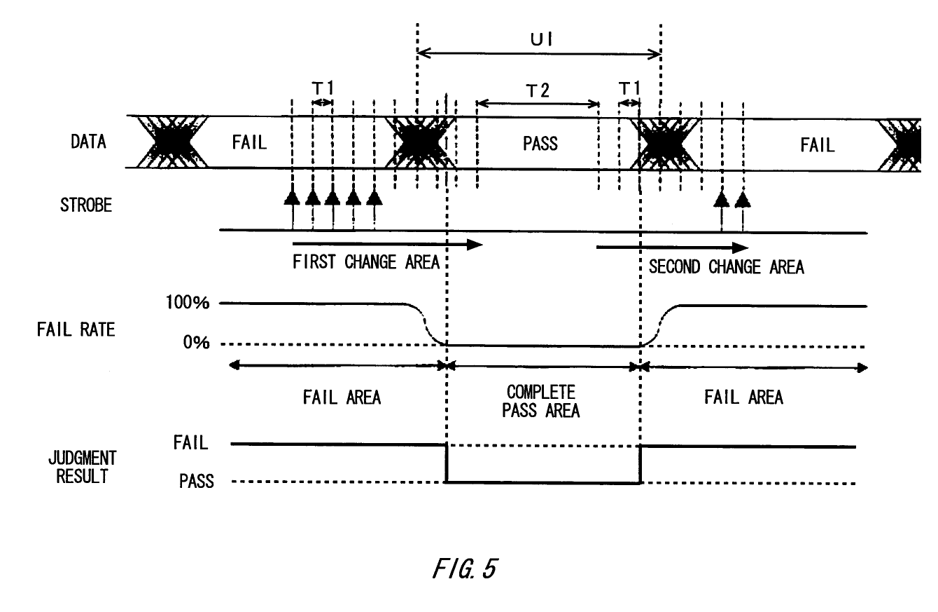

FIG. 5 shows a read training procedure of the semiconductor test apparatus 100 according to the second embodiment. For the purpose of further reducing the time required for detecting the eye opening, the phase control section 40 may change the relative phase at a predetermined interval until the phase detecting section 54 detects the first relative phase. When the phase detecting section 54 has detected the first relative phase, the phase control section 40 may change the relative phase at an interval larger than the predetermined interval, and subsequently change the relative phase at the predetermined interval.

For example, the phase control section 40 sequentially changes the phase of the strobe signal from the initial phase of the first change area shown in FIG. 5, at the interval of T1. The phase control section 40 latches the data received from the device under test 200 by means of the strobe signal, and then transmits the data to the expected value comparing section 52, and the expected value comparing section 52 stores the judgment result to the analysis memory 58. The phase detecting section 54 detects the first relative phase changing from the fail state to the pass state, based on the judgment result stored in the analysis memory 58.

When detecting the first relative phase, the phase detecting section 54 halts changing the relative phase in the first phase change area, and starts changing the relative phase in the second phase change area whose initial phase is set to be the phase whose relative phase has been changed by T2. T2 may be larger than T1 and smaller than 1 UI.

Subsequently in the second phase change area, the phase control section 40 sequentially changes the phase of the strobe signal in the interval of T1. In the second phase change area, the phase detecting section 54 detects the second relative phase changing from the pass state to the fail state, based on the judgment result stored in the analysis memory 58. According to the above-explained procedure, the measurement becomes unnecessary in the period of T2, and so the advantageous effect of reducing the time required for the timing training can be achieved.

The phase control section 40 may determine the first phase change area and the second phase change area in advance. For example, the phase control section 40 may determine the first phase change area to be a phase different from the position assumed to be the central position of the eye opening by 0.4 UI or above and 0.8 UI or below, and the T2 phase area to be to be in a range of 0.4 UI below or above the position assumed to be the central position of the eye opening. Accordingly, it becomes unnecessary to analyze the data for each relative phase, and so even when the time required for analyzing the data is T1 or longer, the first relative phase and the second relative phase can still be detected.

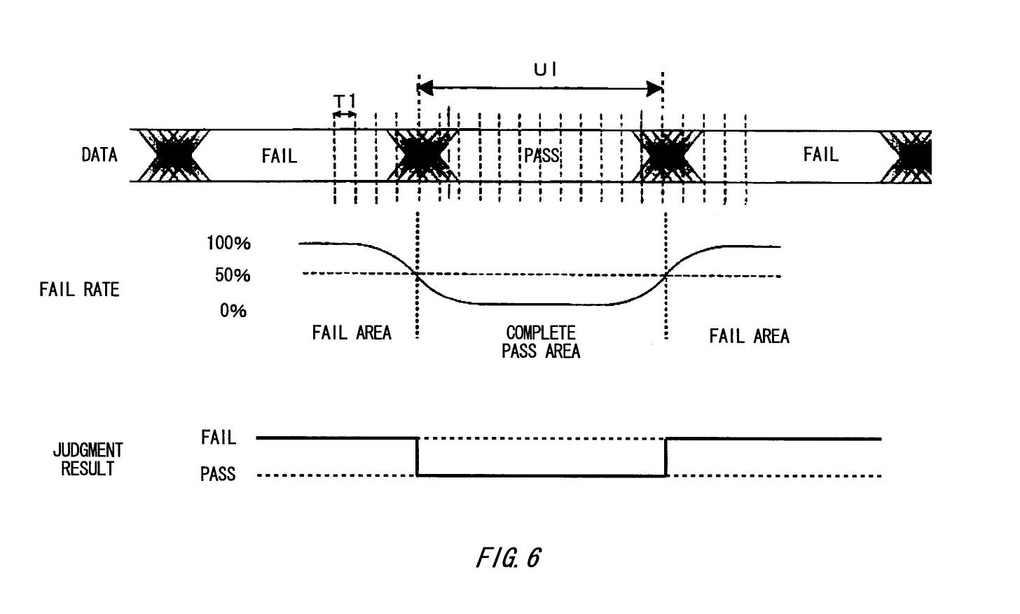

FIG. 6 shows a read training procedure of the semiconductor test apparatus 100 according to the third embodiment. In this embodiment, the phase detecting section 54 may detect the relative phase at which the fail rate is a predetermined ratio, to be the first relative phase changing from the fail state to the pass state. Likewise, the phase detecting section 54 may detect the relative phase at which the fail rate is a predetermined ratio, to be the second relative phase changing from the pass state to the fail state. For example, the predetermined ratio is 50% in FIG. 6. The semiconductor test apparatus 100 may also set the first relative phase, to be the phase resulting from averaging the relative phase at the time of changing from the fail state to the pass state, by a plurality of cycles. Likewise, the semiconductor test apparatus 100 may also set the second relative phase, to be the phase resulting from averaging the relative phase at the time of changing from the pass state to the fail state, by a plurality of cycles.

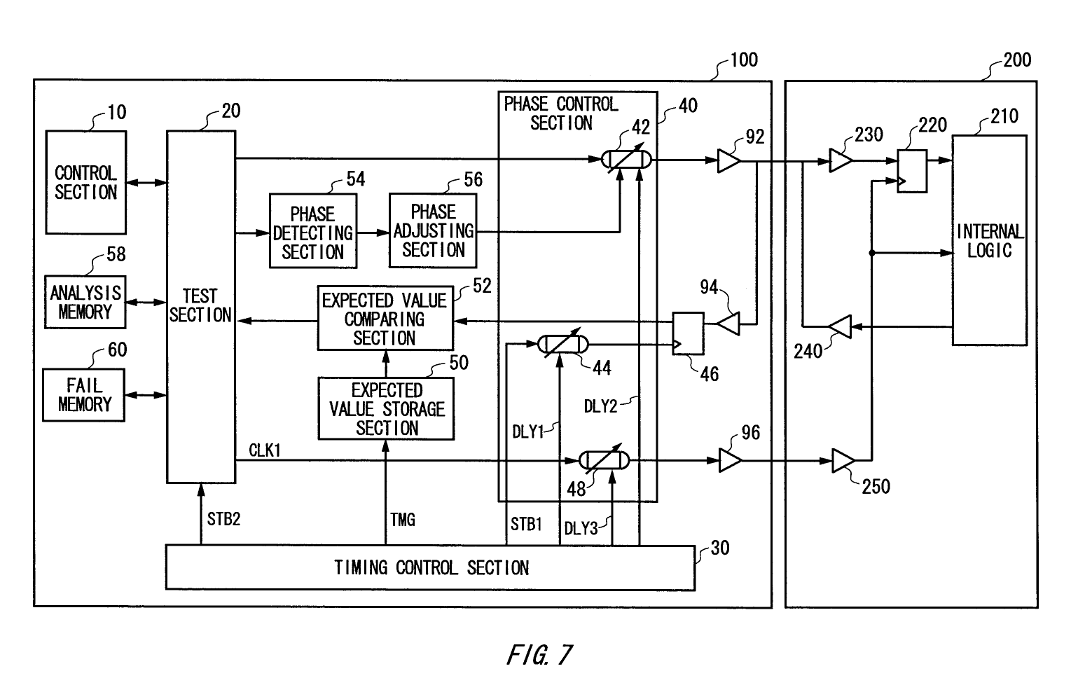

FIG. 7 shows a configuration of the semiconductor test apparatus 100 according to the fourth embodiment. The phase control section 40 may change the phase of at least one of the clock and the inputted data to be supplied to the device under test 200. For example, in write training, the relative phase may be changed by changing the delay amount of the clock, instead of changing the delay amount of the data. In this case, the clock outputted from the test section 20 is inputted to the phase control section 40. The phase control section 40 includes a delay circuit 48, and the delay circuit 48 may change the phase of the clock based on the timing signal DLY3 outputted from the timing control section 30.

The device under test 200 may obtain the data from the semiconductor test apparatus 100, according to the clock whose phase has been changed by the delay circuit 48. In addition, the device under test 200 may transmit the obtained data to the semiconductor test apparatus 100. The expected value comparing section 52 may compare the expected value to the data received from the device under test 200, and the test section 20 may judge pass/fail of the device under test 200 based on the comparison result.

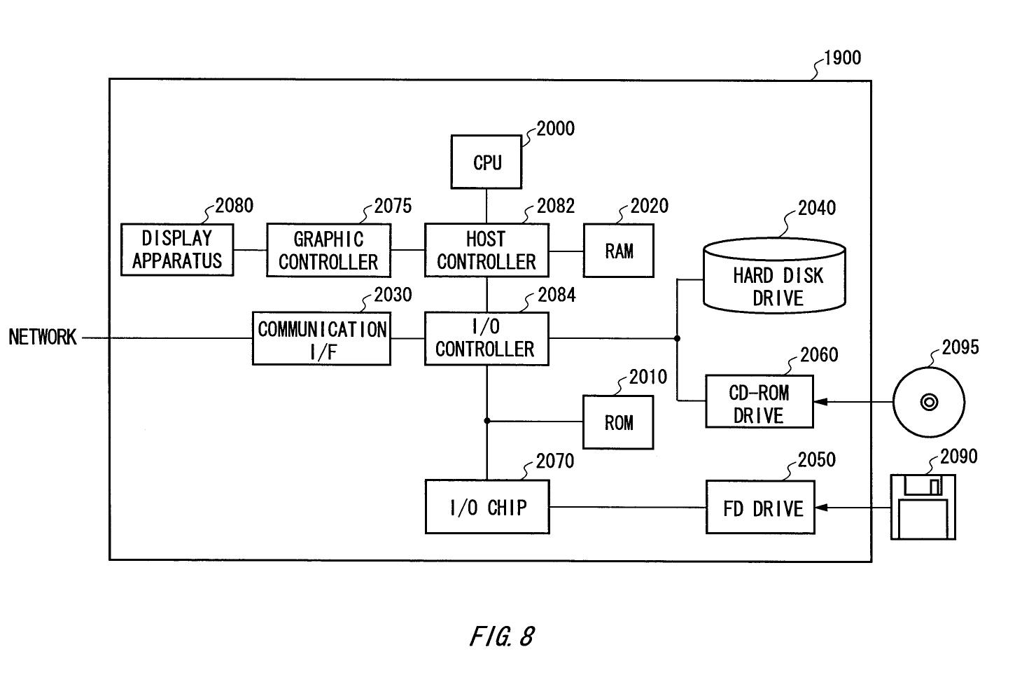

FIG. 8 shows an exemplary configuration of a computer 1900 according to the fifth embodiment. The computer 1900 according to the present embodiment is equipped with a CPU periphery that includes a CPU 2000, a RAM 2020, a graphics controller 2075, and a display apparatus 2080 which are mutually connected by a host controller 2082. The computer 1900 is also equipped with an input/output unit having a communication interface 2030, a hard disk drive 2040, and a CD-ROM drive 2060 which are connected to the host controller 2082 via an input/output controller 2084, and a legacy input/output unit having a ROM 2010, a flexible disk drive 2050, and an input/output chip 2070 which are connected to the input/output controller 2084.

The host controller 2082 connects the RAM 2020 with the CPU 2000 and the graphics controller 2075 which access the RAM 2020 at a high transfer rate. The CPU 2000 operates according to programs stored in the ROM 2010 and the RAM 2020, thereby controlling each unit. The graphics controller 2075 obtains image data generated by the CPU 2000 or the like on a frame buffer provided in the RAM 2020, and causes the image data to be displayed on the display apparatus 2080. Alternatively, the graphics controller 2075 may contain therein a frame buffer for storing image data generated by the CPU 2000 or the like.

The input/output controller 2084 connects the host controller 2082 with the communication interface 2030, the hard disk drive 2040, and the CD-ROM drive 2060, which are relatively high-speed input/output apparatuses. The communication interface 2030 communicates with other apparatuses via a network. The hard disk drive 2040 stores a program and data used by the CPU 2000 within the computer 1900. The CD-ROM drive 2060 reads the program or the data from the CD-ROM 2095, and provides the hard disk drive 2040 with the program or the data via the RAM 2020.

The ROM 2010, and the flexible disk drive 2050 and the input/output chip 2070 which are relatively low-speed input/output apparatuses are connected to the input/output controller 2084. The ROM 2010 stores therein a boot program executed by the computer 1900 at the time of activation, a program depending on the hardware of the computer 1900, or the like. The flexible disk drive 2050 reads the programs or data from a flexible disk 2090, and provides the hard disk drive 2040 with the programs or data via the RAM 2020. The input/output chip 2070 connects a flexible drive 2050 to an input/output controller 2084, and connects various input/output apparatuses via a parallel port, a serial port, a keyboard port, a mouse port, and the like to the input/output controller 2084.

A program to be provided for the hard disk drive 2040 via the RAM 2020 is provided by a user by being stored in such a recording medium as the flexible disk 2090, the CD-ROM 2095, and an IC card. The program is read from the recording medium, installed into the hard disk drive 2040 within the computer 1900 via the RAM 2020, and executed in the CPU 2000.

A program that is installed in the computer 1900 and causes the computer 1900 to function as a semiconductor test apparatus 100 causes the computer 1900 to function as: a phase control module that sequentially changes a relative phase of input/output data of the device under test 200 and a pre-set strobe signal, into one pre-set direction; an expected value comparing module that judges whether a value resulting from sampling the input/output data using the strobe signal matches a pre-set expected value a pre-set number of times at each relative phases; a phase detecting module that detects a first relative phase changing from a fail state to a pass state and a second relative phase changing from the pass state to the fail state, the fail state being in which at least one of the pre-set number of judgment results indicates mismatch, and the pass state being in which all the pre-set number of judgment results indicate match; a phase adjusting module that adjusts a phase of a test signal to be supplied to the device under test based on the first relative phase and the second relative phase detected by the phase detecting module; and a test module that tests the device under test using the test signal whose phase has been adjusted by the phase adjusting module. The program or module acts on the CPU 2000, to cause the computer 1900 to function as any of the semiconductor test apparatus 100.

The information processing described in these programs is read into the computer 1900, to function as the phase control section 40, the expected value comparing section 52, the phase detecting section 54, the phase adjusting section 56, and the test section 20, which are the concrete means as a result of cooperation between the software and the above-mentioned various types of hardware resources. Moreover, the semiconductor test apparatus 100 for the usage is constituted by realizing the operation or processing of information in accordance with the usage of the computer 1900 of the present embodiment by these concrete means.

For example when communication is performed between the computer 1900 and an external apparatus and the like, the CPU 2000 executes a communication program loaded onto the RAM 2020, to instruct communication processing to a communication interface 2030, based on the processing described in the communication program. The communication interface 2030, under control of the CPU 2000, reads the transmission data stored on the transmission buffering region provided in the recording apparatus such as a RAM 2020, a hard disk drive 2040, a flexible disk 2090, or a CD-ROM 2095, and transmits the read transmission data to a network, or writes reception data received from a network to a reception buffering region or the like provided on the recording apparatus. In this way, the communication interface 2030 may exchange transmission/reception data with the recording apparatus by a DMA (direct memory access) method, or by a configuration that the CPU 2000 reads the data from the recording apparatus or the communication interface 2030 of a transfer destination, to write the data into the communication interface 2030 or the recording apparatus of the transfer destination, so as to transfer the transmission/reception data.

In addition, the CPU 2000 causes all or a necessary portion of the file of the database to be read into the RAM 2020 such as by DMA transfer, the file or the database having been stored in an external recording apparatus such as the hard disk drive 2040, the CD-ROM drive 2060 (CD-ROM 2095), the flexible disk drive 2050 (flexible disk 2090), to perform various types of processing onto the data on the RAM 2020. The CPU 2000 then writes back the processed data to the external recording apparatus by means of a DMA transfer method or the like.

In such processing, the RAM 2020 can be considered to temporary store the contents of the external recording apparatus, and so the RAM 2020, the external recording apparatus, and the like are collectively referred to as a memory, a storage section, or a recording apparatus, and so on in the present embodiment. In the present embodiment, various types of information such as various types of programs, data, tables, and databases are stored in the recording apparatus, to undergo information processing. Note that the CPU 2000 may also retain a part of the RAM 2020, to perform reading/writing thereto on the cache memory. In such an embodiment, too, the cache is considered to be contained in the RAM 2020, the memory, and/or the recording apparatus unless noted otherwise, since the cache memory performs part of the function of the RAM 2020.

The CPU 2000 performs various types of processing, onto the data read from the RAM 2020, which includes various types of operations, processing of information, condition judging, search/replace of information, described in the present embodiment and designated by an instruction sequence of programs, and writes the result back to the RAM 2020. For example, when performing condition judging, the CPU 2000 judges whether each type of variables shown in the present embodiment is larger, smaller, no smaller than, no greater than, or equal to the other variable or constant, and when the condition judging results in the affirmative (or in the negative), the process branches to a different instruction sequence, or calls a sub routine.

In addition, the CPU 2000 can search for information in the file or database or the like in the recording apparatus. For example when a plurality of entries, each having an attribute value of a first attribute is associated with an attribute value of a second attribute, are stored in a recording apparatus, the CPU 2000 searches for an entry matching the condition whose attribute value of the first attribute is designated, from among the plurality of entries stored in the recording apparatus, and reads the attribute value of the second attribute stored in the entry, thereby obtaining the attribute value of the second attribute associated with the first attribute satisfying the predetermined condition.

The above-explained program or module can be stored in an external recording medium. Exemplary recording medium include a flexible disk 2090, a CD-ROM 2095, as well as an optical recording medium such as a DVD or a CD, a magneto-optic recording medium such as a MO, a tape medium, and a semiconductor memory such as an IC card. In addition, a recording apparatus such as a hard disk or a RAM provided in a server system connected to a dedicated communication network or the Internet can be used as a recording medium, thereby providing the program to the computer 1900 via the network.

While the embodiment(s) of the present invention has (have) been described, the technical scope of the invention is not limited to the above described embodiment(s). It is apparent to persons skilled in the art that various alterations and improvements can be added to the above-described embodiment(s). It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, specification, or drawings, it does not necessarily mean that the process must be performed in this order.

As made clear from the above, the embodiments of the present invention has an advantageous effect of quickly detecting the both ends of the eye opening, by sequentially changing a relative phase of data and a strobe, into one direction, and comparing an expected value to data exchanged between the semiconductor test apparatus 100 and the device under test 200. Furthermore, by setting the phase at which the changing the relative phase should start, to the phase at which the expected value is assumed not to match the received data, the both ends of the eye opening can be detected even more quickly.

What is claimed is:

1. A test apparatus for testing a device under test, comprising:
a phase control section that sequentially changes a relative phase of input/output data of the device under test and a pre-set strobe signal, into one pre-set direction;
an expected value comparing section that judges whether a value resulting from sampling the input/output data using the strobe signal matches a pre-set expected value a pre-set number of times at each relative phases;
a phase detecting section that detects a first relative phase changing from a fail state to a pass state and a second relative phase changing from the pass state to the fail state, the fail state being in which at least one of the pre-set number of judgment results indicates mismatch, and the pass state being in which all the pre-set number of judgment results indicate match;
a phase adjusting section that adjusts a phase of a test signal to be supplied to the device under test based on the first relative phase and the second relative phase detected by the phase detecting section; and
a test section that tests the device under test using the test signal whose phase has been adjusted by the phase adjusting section.

2. The test apparatus according to claim 1, wherein
the phase control section sets an initial phase of the strobe signal to a phase in which the fail state is detected.

3. The test apparatus according to claim 1, wherein
the phase control section sequentially changes a phase of the strobe signal used for sampling output data of the device under test.

4. The test apparatus according to claim 1, wherein
the phase control section sequentially changes a relative phase of input data provided to the device under test and the strobe signal used for sampling the input data inside the device under test, in the pre-set one direction.

5. The test apparatus according to claim 4, wherein
the phase control section changes a phase of at least one of a clock and input data provided to the device under test.

6. The test apparatus according to claim 5, wherein
the expected value comparing section receives, from the device under test, a value of the input data obtained by the device under test according to the strobe signal.

7. The test apparatus according to claim 1, wherein
the phase control section changes the relative phase at a pre-set interval until the phase detecting section detects the first relative phase, and when the phase detecting section has detected the first relative phase, the phase control section changes the relative phase at the pre-set interval after changing the relative phase at an interval larger than the pre-set interval.

8. A test method for testing a device under test, comprising:
sequentially changing a relative phase of input/output data of the device under test and a pre-set strobe signal, into one pre-set direction;
judging whether a value resulting from sampling the input/output data using the strobe signal matches a pre-set expected value a pre-set number of times at each relative phases;
detecting a first relative phase changing from a fail state to a pass state and a second relative phase changing from the pass state to the fail state, the fail state being in which at least one of the pre-set number of judgment results indicates mismatch, and the pass state being in which all the pre-set number of judgment results indicate match;
adjusting a phase of a test signal to be supplied to the device under test based on the first relative phase and the second relative phase; and
testing the device under test using the test signal whose phase has been adjusted.

9. A recording medium storing a program to operate a test apparatus that tests a device under test, the program causing the test apparatus to function as:
a phase control section that sequentially changes a relative phase of input/output data of the device under test and a pre-set strobe signal, into one pre-set direction;
an expected value comparing section that judges whether a value resulting from sampling the input/output data using the strobe signal matches a pre-set expected value a pre-set number of times at each relative phases;
a phase detecting section that detects a first relative phase changing from a fail state to a pass state and a second relative phase changing from the pass state to the fail state, the fail state being in which at least one of the pre-set number of judgment results indicates mismatch, and the pass state being in which all the pre-set number of judgment results indicate match;
a phase adjusting section that adjusts a phase of a test signal to be supplied to the device under test based on the first relative phase and the second relative phase detected by the phase detecting section; and
a test section that tests the device under test using the test signal whose phase has been adjusted by the phase adjusting section.
